(19) United States
(12) Patent Application Publication
(10) Pub. No.: US 2021/0247147 A1
(43) Pub. Date: Aug. 12, 2021

(54) VAPOR CHAMBER STRUCTURE AND MANUFACTURING METHOD THEREOF

(71) Applicant: Unimicron Technology Corp., Taoyuan City (TW)

(72) Inventors: Ra-Min Tain, Hsinchu County (TW); John Hon-Shing Lau, Taoyuan City (TW); Pu-Ju Lin, Hsinchu City (TW); Wei-Ci Ye, Taoyuan City (TW); Chi-Hai Kuo, Taoyuan City (TW); Cheng-Ta Ko, Taipei City (TW); Tzyy-Jang Tseng, Taoyuan City (TW)

(73) Assignee: Unimicron Technology Corp., Taoyuan City (TW)

(21) Appl. No.: 17/168,200

(22) Filed: Feb. 5, 2021

Related U.S. Application Data
(63) Continuation-in-part of application No. 17/017,702, filed on Sep. 11, 2020.
(60) Provisional application No. 62/972,050, filed on Feb. 9, 2020.

(30) Foreign Application Priority Data
Jul. 14, 2020 (TW) 109123680
Nov. 9, 2020 (TW) 109138973

(51) Int. Cl. F28D 15/04; F28D 15/02; F28F 21/08; F28F 3/10; B23P 15/26

(52) U.S. Cl. CPC F28D 15/046; F28D 15/0233; F28D 15/0266; F28D 15/0283; F28F 2260/02; F28F 3/10; B23P 15/26; F28D 2015/0225; F28F 21/081

(57) ABSTRACT

A vapor chamber structure including a thermally conductive shell, a capillary structure layer, and a working fluid is provided. The thermally conductive shell includes a first thermally conductive portion and a second thermally conductive portion. The first thermally conductive portion has at least one first cavity. The second thermally conductive portion and the first cavity define at least one sealed chamber, and a pressure in the sealed chamber is lower than a standard atmospheric pressure. The capillary structure layer covers an inner wall of the sealed chamber. The working fluid is filled in the sealed chamber.

### CROSS-REFERENCE TO RELATED APPLICATION

This application is a continuation-in-part application of and claims the priority benefit of a prior application Ser. No. 17/017,702, filed on Sep. 11, 2020. This application also claims the priority benefit of Taiwan application serial no. 109138973, filed on Nov. 9, 2020. The entirety of each of the above-mentioned patent applications is hereby incorporated by reference herein.

### BACKGROUND

### Technical Field

The disclosure relates to a thermally conductive structure and a manufacturing method thereof, and in particular to a vapor chamber structure and a manufacturing method thereof.

### Description of Related Art

Existing vapor chambers are mostly installed on an outer edge of an electronic system and between an electronic component or a circuit board and a cooling plate. Since the thickness of the vapor chambers are mostly above 1 mm, it is difficult to place the vapor chambers in, for example, a mobile phone shell. This limits the application range of the vapor chambers. In addition, an outer layer of the vapor chambers is generally made of a polymer material, and the polymer material has a heat dissipation coefficient of two orders of magnitude lower than that of metallic copper. Also, a thermally conductive material layer in the vapor chambers generally has a complex structure and requires a high manufacturing cost. Therefore, there is an urgent need to reduce the thickness, reduce the manufacturing cost, and simplify the manufacturing process of the vapor chambers in an effective way.

### SUMMARY

The disclosure provides a vapor chamber structure having a small thickness.

The disclosure further provides a manufacturing method of a vapor chamber structure, which is used to manufacture the above-mentioned vapor chamber structure and has simple manufacturing steps and low cost, in which a vapor chamber structure having a small thickness is manufactured.

A vapor chamber structure of the disclosure includes a thermally conductive shell, a capillary structure layer, and a working fluid. The thermally conductive shell includes a first thermally conductive portion and a second thermally conductive portion. The first thermally conductive portion has at least one first cavity. The second thermally conductive portion and the first cavity define at least one sealed chamber, and a pressure in the sealed chamber is lower than a standard atmospheric pressure. The capillary structure layer covers an inner wall of the sealed chamber. The working fluid is filled in the sealed chamber.

In an embodiment of the disclosure, the capillary structure layer includes a first capillary structure portion and a second capillary structure portion. The first capillary structure portion at least covers an inner wall of the first cavity, and the second capillary structure portion is configured on the second thermally conductive portion.

In an embodiment of the disclosure, the first thermally conductive portion and the second thermally conductive portion are an integrally formed thermally conductive plate. The thermally conductive shell is formed by folding the thermally conductive plate in half and then sealing the thermally conductive plate.

In an embodiment of the disclosure, the second thermally conductive portion has at least one second cavity, and the second capillary structure portion at least covers an inner wall of the second cavity. The sealed chamber is defined between the thermally conductive plate, the first cavity and the second cavity. An extension direction of the first cavity is different from an extension direction of the second cavity.

In an embodiment of the disclosure, the thermally conductive shell is formed by overlapping a first thermally conductive portion and a second thermally conductive portion and then sealing the first thermally conductive portion and the second thermally conductive portion. The first thermally conductive portion and the second thermally conductive portion are a first thermally conductive plate and a second thermally conductive plate, respectively.

In an embodiment of the disclosure, the second thermally conductive plate has at least one second cavity, and the second capillary structure portion at least covers an inner wall of the second cavity. The sealed chamber is defined between the first thermally conductive plate, the second thermally conductive plate, the first cavity and the second cavity.

In an embodiment of the disclosure, the capillary structure layer is a porous structure layer or a surface microstructure layer of the thermally conductive shell.

In an embodiment of the disclosure, a material of the thermally conductive shell includes ceramics or a stacked material of a metal and an alloy.

In an embodiment of the disclosure, the working fluid includes water.

In an embodiment of the disclosure, a thickness of the capillary structure layer is less than or equal to half of a thickness of the thermally conductive shell.

A manufacturing method of a vapor chamber structure of the disclosure includes the following. A thermally conductive plate is provided. The thermally conductive plate has a configuration area and a peripheral area surrounding the configuration area. At least one cavity is formed in the configuration area of the thermally conductive plate. A capillary structure layer is formed in the configuration area of the thermally conductive plate. The capillary structure layer covers the thermally conductive plate and an inner wall of the cavity. The thermally conductive plate is folded in half, and the peripheral area of the thermally conductive plate is sealed to form at least one chamber, and the capillary structure layer is located in the chamber. A vacuuming process is performed on the chamber and a working fluid is provided into the chamber. The chamber is completely sealed so as to form at least one sealed chamber.

In an embodiment of the disclosure, the thermally conductive plate has a first flap and a second flap opposite to each other, and the configuration area connects the first flap and the second flap. A vacuuming process is performed on the chamber between the first flap and the second flap, and the working fluid is provided into the chamber between the first flap and the second flap. A space between the first flap and the second flap is sealed so as to completely seal the chamber.

In an embodiment of the disclosure, a method of forming the capillary structure layer includes performing an etching process or an electroplating process or a printing process or a laser process or a sintering process on the thermally conductive plate, and forming the capillary structure layer on a surface of the thermally conductive plate.

In an embodiment of the disclosure, the capillary structure layer is made of a porous medium, and a pore size of the porous medium is between 5 μm and 50 μm.

In an embodiment of the disclosure, a method of completely sealing the chamber includes a mechanical clamping process or a diffusion bonding process or a welding process or a soldering process or an adhesion process.

A manufacturing method of a vapor chamber structure of the disclosure includes the following. A first thermally conductive plate and a second thermally conductive plate are provided. The first thermally conductive plate has a first configuration area and a first peripheral area surrounding the first configuration area. The second thermally conductive plate has a second configuration area and a second peripheral area surrounding the second configuration area. At least one first cavity is formed in the first configuration area of the first thermally conductive plate. A first capillary structure portion is formed on an inner wall of the first cavity. A second capillary structure portion is formed in the second configuration area of the second thermally conductive plate. The second thermally conductive plate is superimposed on the first thermally conductive plate, and the first peripheral area of the first thermally conductive plate and the second peripheral area of the second thermally conductive plate are sealed to form at least one chamber. The first capillary structure portion and the second capillary structure portion define a capillary structure layer and the capillary structure layer is located in the chamber. A vacuuming process is performed on the chamber and a working fluid is provided into the chamber. The chamber is completely sealed so as to form at least one sealed chamber.

In an embodiment of the disclosure, the first thermally conductive plate has a first flap, and the second thermally conductive plate has a second flap. When the second thermally conductive plate is superimposed on the first thermally conductive plate, the second flap overlaps the first flap. A vacuuming process is performed on the chamber between the first flap and the second flap, and the working fluid is provided into the chamber between the first flap and the second flap. A space between the first flap and the second flap is sealed so as to completely seal the chamber.

In an embodiment of the disclosure, a method of forming the first capillary structure portion and the second capillary structure portion includes performing an etching process or an electroplating process or a printing process or a laser process or a sintering process on the first thermally conductive plate and the second thermally conductive plate, respectively, and forming the first capillary structure portion on a first surface of the first thermally conductive plate and forming the second capillary structure portion on a second surface of the second thermally conductive plate.

In an embodiment of the disclosure, a method of completely sealing the chamber includes a mechanical clamping process or a diffusion bonding process or a welding process or a soldering process or an adhesion process.

In an embodiment of the disclosure, before the second capillary structure portion is formed in the second configuration area of the second thermally conductive plate, at least one second cavity is formed in the second configuration area of the second thermally conductive plate.

Based on the above, in the manufacturing method of a vapor chamber structure of the disclosure, the capillary structure layer covers the thermally conductive plate and the inner wall of the cavity, and the thermally conductive plate is folded in half and the peripheral area of the thermally conductive plate is sealed to form the chamber. Next, the vacuuming process is performed on the chamber and the working fluid is provided into the chamber. Next, the chamber is completely sealed, and the working fluid is filled in the sealed chamber. Therefore, by manufacturing the thermally conductive shell of the vapor chamber structure of the disclosure using the thermally conductive plate, the vapor chamber structure of the disclosure has a small thickness. In addition, the manufacture of the vapor chamber structure of the disclosure is simple and low in cost.

In order to make the features and advantages of the disclosure more comprehensible, the following specific embodiments are described in detail in connection with accompanying drawings.

### BRIEF DESCRIPTION OF THE DRAWINGS

FIGS. 1A to 1D are schematic cross-sectional views of a manufacturing method of a vapor chamber structure according to an embodiment of the disclosure.

FIGS. 2A to 2C are schematic top views of some steps of the manufacturing method of a vapor chamber structure of FIGS. 1A to 1D.

FIGS. 3A and 3B are respectively a schematic top view and a schematic cross-sectional view of some steps of a manufacturing method of a vapor chamber structure according to another embodiment of the disclosure.

FIG. 4 is a schematic top view of a vapor chamber structure according to another embodiment of the disclosure.

FIGS. 5A to 5B are schematic cross-sectional views of some steps of a manufacturing method of a vapor chamber structure according to another embodiment of the disclosure.

FIGS. 6A to 6B are schematic top views of the manufacturing method of a vapor chamber structure of FIGS. 5A and 5B.

FIGS. 7A to 7C are schematic views of some steps of a manufacturing method of a vapor chamber structure according to another embodiment of the disclosure.

FIGS. 8A and 8B are respectively a schematic top view and a schematic cross-sectional view of an electronic device which adopts the vapor chamber structure of the disclosure.

FIG. 8C is a schematic cross-sectional view of another electronic device which adopts the vapor chamber structure of the disclosure.

### DESCRIPTION OF THE EMBODIMENTS

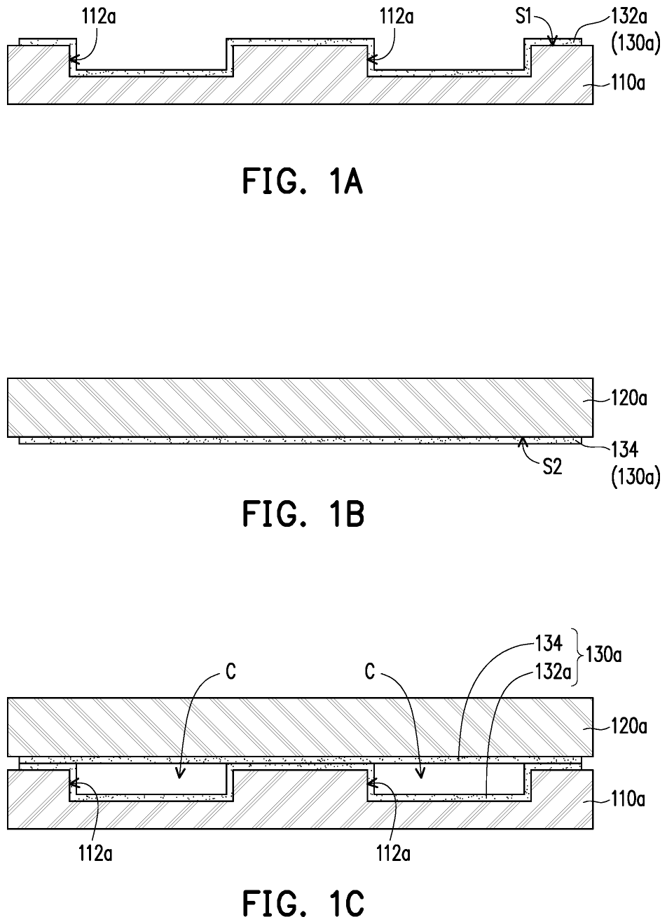

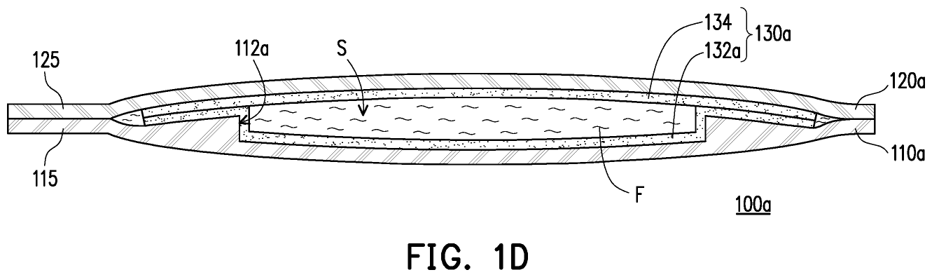

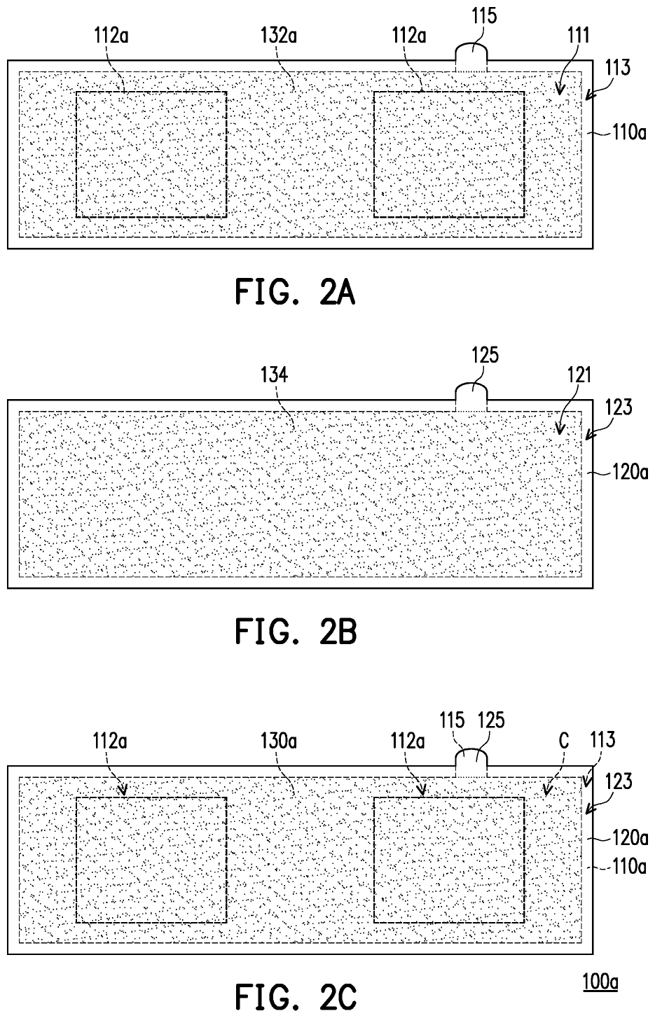

FIGS. 1A to 1D are schematic cross-sectional views of a manufacturing method of a vapor chamber structure according to an embodiment of the disclosure. FIGS. 2A to 2C are schematic top views of some steps of the manufacturing method of a vapor chamber structure of FIGS. 1A to 1D. Regarding the manufacturing method of a vapor chamber structure of this embodiment, first, referring to FIGS. 1A and 2A together, a first thermally conductive plate 110a is provided. The first thermally conductive plate 110a has a first configuration area 111 and a first peripheral area 113 surrounding the first configuration area 111. Furthermore, the first thermally conductive plate 110a of this embodiment has a first flap 115. Here, a material of the first thermally conductive plate 110a includes, for example, ceramics or a stacked material of a metal and an alloy. In the case where the material of the first thermally conductive plate 110a includes a stacked material of a metal and an alloy, the metal and the alloy are, for example, pure copper and a copper/nickel/silicon alloy, respectively, in which the thickness of the copper/nickel/silicon alloy is greater than the thickness of pure copper, and the overall structural strength is increased.

Next, referring to FIGS. 1A and 2A together again, at least one first cavity (two first cavities 112a are schematically shown) is formed in the first configuration area 111 of the first thermally conductive plate 110a. Here, a method of forming the first cavity 112a is, for example but not limited to, etching, laser drilling, or mechanical drilling. Specifically, the first cavity 112a is provided to allow a space for diffusion and movement of a later-described liquid working fluid F (referring to FIG. 1D) located in a capillary structure layer 130a (referring to FIG. 1C) after vaporization and before condensation of the working fluid F.

Next, referring to FIG. 1A and FIG. 2A together again, a first capillary structure 132a is formed on an inner wall of the first cavity 112a. The thickness of the first capillary structure portion 132a is less than or equal to half of the thickness of the first thermally conductive plate 110a. Here, a method of forming the first capillary structure portion 132a is, for example, performing an etching process or an electroplating process or a printing process or a laser process or a sintering process on the first thermally conductive plate 110a, and the first capillary structure portion 132a is formed on a first surface 51 of the first thermally conductive plate 110a. In other embodiments, the capillary structure portion may also be made of a porous medium, and a pore size of the porous medium is between 5 μm and 50 μm, which are still within the scope of the disclosure.

Next, referring to FIGS. 1B and 2B together, a second thermally conductive plate 120a is provided. The second thermally conductive plate 120a has a second configuration area 121 and a second peripheral area 123 surrounding the second configuration area 121. Furthermore, the second thermally conductive plate 120a has a second flap 125. Here, the first thermally conductive plate 110a and the second thermally conductive plate 120a are completely the same in size and material.

Next, referring to FIGS. 1B and 2B together again, a second capillary structure portion 134 is formed in the second configuration area 121 of the second thermally conductive plate 120a. The thickness of the second capillary structure portion 134 is less than or equal to half of the thickness of the second thermally conductive plate 120a. Here, a method of forming the second capillary structure portion 134 is, for example, performing an etching process or an electroplating process or a printing process or a laser process or a sintering process on the second thermally conductive plate 120a, and the second capillary structure portion 134 is formed on a second surface S2 of the second thermally conductive plate 120a. In other embodiments, the capillary structure portion may also be made of a porous medium, and a pore size of the porous medium is between 5 μm and 50 μm, which are still within the scope of the disclosure.

Next, referring to FIGS. 1C and 2C together, the second thermally conductive plate 120a is superimposed on the first thermally conductive plate 110a, and the second flap 125 overlaps the first flap 115. Moreover, the first peripheral area 113 of the first thermally conductive plate 110a and the second peripheral area 123 of the second thermally conductive plate 120a are sealed to form at least one chamber (two chambers C are schematically shown). At this time, an inner wall of the chamber C is covered with the first capillary structure portion 132a and the second capillary structure portion 134, and the first capillary structure portion 132a and the second capillary structure portion 134 define the capillary structure layer 130a. Here, a method of sealing the first peripheral area 113 and the second peripheral area 123 is, for example, a mechanical clamping process or a diffusion bonding process or a welding process or a soldering process or an adhesion process.

Next, referring to FIGS. 1C, 1D and 2C together, a vacuuming process is performed on the chamber C, and the working fluid F is provided into the chamber C. Specifically, the vacuuming process is performed on the chamber C between the first flap 115 and the second flap 125, and the working fluid F is provided into the chamber C between the first flap 115 and the second flap 125. The chamber C is completely sealed so as to form at least one sealed chamber S, and the working fluid F is filled in the sealed chamber S. It is to be noted that the sealed chamber S should not be fully filled with the working fluid F, because vapor generated by evaporation of the working fluid F requires space for movement. When a vapor chamber structure 100a is not heated, the working fluid F exists in the capillary structure layer 130a. After the vapor chamber structure 100a is heated, the working fluid F becomes vapor and enters the sealed chamber S. When the vapor is condensed, the working fluid F returns into the capillary structure layer 130a. Here, a space between the first flap 115 and the second flap 125 is sealed to completely seal the chamber C. A method of completely sealing chamber C is, for example, a mechanical clamping process or a diffusion bonding process or a welding process or a soldering process or an adhesion process, and the working fluid F is, for example, water. Up to this point, the manufacture of the vapor chamber structure 100a is completed.

In terms of structure, referring to FIG. 1D again, the vapor chamber structure 100a of this embodiment includes a thermally conductive shell, the capillary structure layer 130a, and the working fluid F. The thermally conductive shell is formed by overlapping the first thermally conductive portion and the second thermally conductive portion and then sealing the first thermally conductive portion and the second thermally conductive portion. The first thermally conductive portion and the second thermally conductive portion are the first thermally conductive plate 110a and the second thermally conductive plate 120a, respectively. In other words, the thermally conductive shell of this embodiment is formed by overlapping the first thermally conductive plate 110a and the second conductive plate 120a and then sealing the first thermally conductive plate 110a and the second conductive plate 120a. The first thermally conductive plate 110a has the first cavity 112a. The second thermally conductive plate 120a and the first cavity 112a define the sealed chamber S. The pressure in the sealed chamber S is lower than a standard atmospheric pressure. Therefore, the boiling temperature of the working fluid F (for example, water) in the sealed chamber S is about 60° C. Here, a material of the thermally conductive shell includes ceramics or a stacked material of a metal and an alloy. The capillary structure layer 130a covers an inner wall of the sealed chamber S. The capillary structure layer 130a includes the first capillary structure portion 132a and the second capillary structure portion 134 and transports the working fluid F by capillary action. The first capillary structure portion 132a covers at least an inner wall of the first cavity 112a, and the second capillary structure portion 134 is configured on the second thermally conductive plate 120a. Here, the thickness of the capillary structure layer 130a is less than or equal to half of the thickness of the thermally conductive shell. The working fluid F is filled in the sealed chamber S. The working fluid F is, for example, water. The overall thickness of the vapor chamber structure 100a of this embodiment is preferably less than 300 μm, and preferably less than or equal to 0.25 mm.

In short, the thermally conductive shell of the vapor chamber structure 100a of this embodiment is formed by overlapping the first thermally conductive plate 110a and the second conductive plate 120a and then sealing the first thermally conductive plate 110a and the second conductive plate 120a. Therefore, the vapor chamber structure 100a of this embodiment may have a small thickness. In addition, the manufacture of the vapor chamber structure 100a of this embodiment is simple and low in cost.

It is to be noted that the reference numerals and a part of the description of the foregoing embodiments are applied in the following embodiments, in which the same reference numerals denote the same or similar components, and the description of the same technical content is omitted. Reference can be made to the foregoing embodiments for the omitted description.

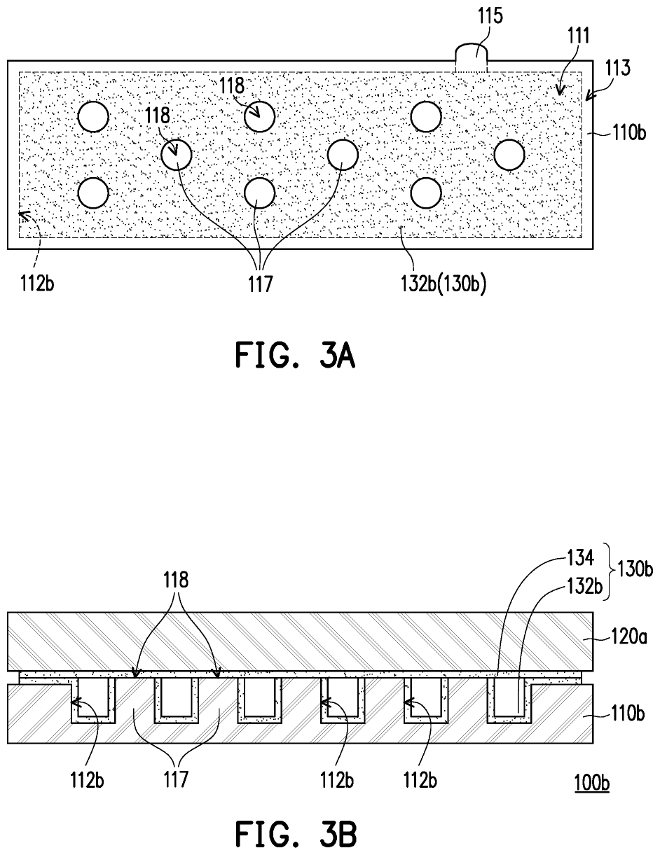

FIGS. 3A and 3B are respectively a schematic top view and a schematic cross-sectional view of some steps of a manufacturing method of a vapor chamber structure according to another embodiment of the disclosure. Referring to FIGS. 2A, 3A and 3B together, a vapor chamber structure 100b of this embodiment is similar to the vapor chamber structure 100a described above (referring to FIG. 2C). The differences between the vapor chamber structure 100b and the vapor chamber structure 100a are: a first thermally conductive plate 110b of this embodiment has only one first cavity 112b, multiple pillars 117 are distributed in the first cavity 112b, and a first capillary structure portion 132b is not provided on a top surface 118 of each of the pillars 117. Specifically, referring to FIGS. 3A and 3B together again, in this embodiment, the first capillary structure portion 132b of a capillary structure layer 130b covers the first configuration area 111 and an inner wall of the first cavity 112b, and the top surface 118 of each of the pillars 117 is exposed. Here, the pillar 117 and the first thermally conductive plate 110b are integrally formed. The pillar 117 is provided to prevent the second thermally conductive plate 120a from collapsing during sealing and vacuuming with the first thermally conductive plate 110b. When the second thermally conductive plate 120a is superimposed on the first thermally conductive plate 110b, the second capillary structure portion 134 overlaps the first capillary structure portion 132b and covers the top surface 118 of each of the pillars 117. Next, the processes such as sealing, vacuuming, providing of the working fluid F (referring to FIG. 1D), and complete sealing are performed, thereby completing the manufacture of the vapor chamber structure 100b. In another unshown embodiment, the first capillary structure portion may be configured on the top surface of each of the pillars, which is still within the scope of the disclosure.

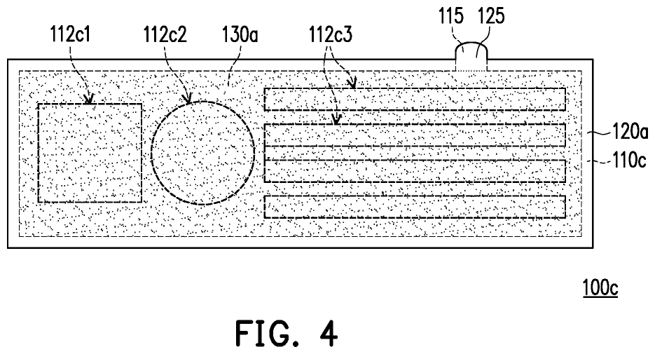

FIG. 4 is a schematic top view of a vapor chamber structure according to another embodiment of the disclosure. Referring to FIGS. 2C and 4 together, a vapor chamber structure 100c of this embodiment is similar to the vapor chamber structure 100a described above. The differences between the vapor chamber structure 100c and the vapor chamber structure 100a are: a first thermally conductive plate 110c in this embodiment has multiple first cavities 112c1, 112c2, and 112c3. The first cavity 112c1 has a square shape, the first cavity 112c2 has a circular shape, and the first cavity 112c3 has a rectangular shape. In other words, the first cavities 112c1, 112c2, and 112c3 have different shapes from each other, and their shapes may be varied according to a heat source configuration in actual application.

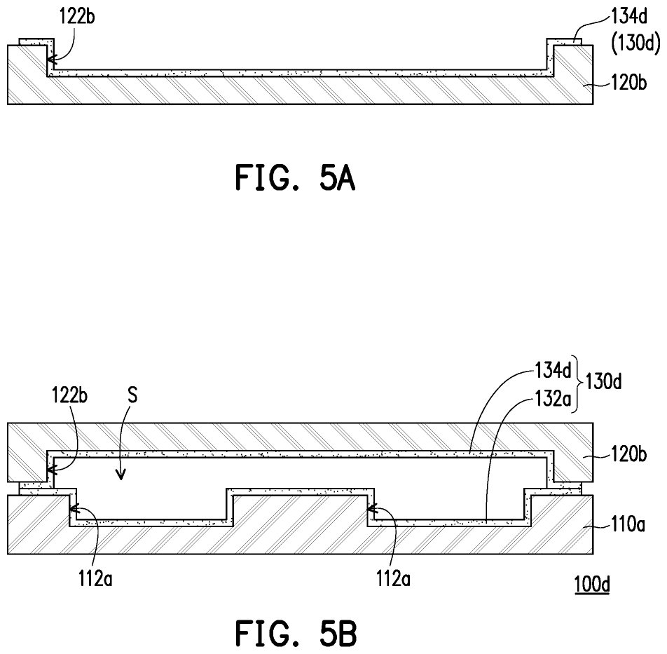

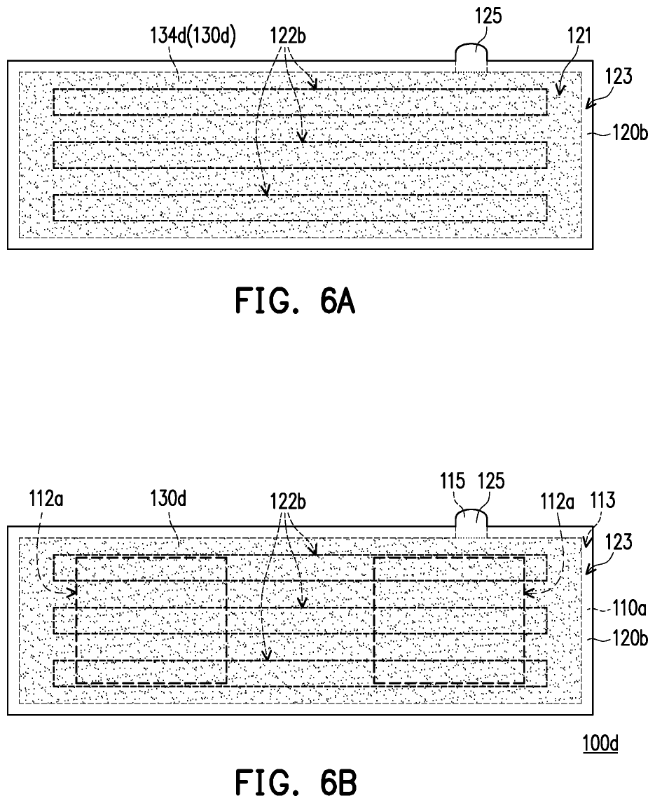

FIGS. 5A to 5B are schematic cross-sectional views of some steps of a manufacturing method of a vapor chamber structure according to another embodiment of the disclosure. FIGS. 6A to 6B are schematic top views of the manufacturing method of a vapor chamber structure of FIGS. 5A and 5B. Referring to FIG. 2B and FIG. 6A together first, a vapor chamber structure 100d (referring to FIG. 5B) of this embodiment is similar to the vapor chamber structure 100a (referring to FIG. 1D). The differences between the vapor chamber structure 100d and the vapor chamber structure 100a are: before a second capillary structure portion 134d is formed in the second configuration area 121 of a second thermally conductive plate 120b, at least one second cavity (three second cavities 122b are schematically shown in FIG. 6A) is formed in the second configuration area 121 of the second thermally conductive plate 120b.

Specifically, referring to FIGS. 5A, 5B, 6A, and 6B together, in this embodiment, the second thermally conductive plate 120b has the second cavity 122b, the second capillary structure portion 134d covers an inner wall of the second cavity 122b and extends to cover the second configuration area 121. Then, the second thermally conductive plate 120b is superimposed on the first thermally conductive plate 110a, and the second flap 125 overlaps the first flap 115. Next, the processes such as sealing, vacuuming, providing of the working fluid F (referring to FIG. 1D), and complete sealing are performed, thereby completing the manufacture of the vapor chamber structure 100d. Here, the sealed chamber S is defined between the first thermally conductive plate 110a, the second thermally conductive plate 120b, the first cavity 112a, and the second cavity 112b.

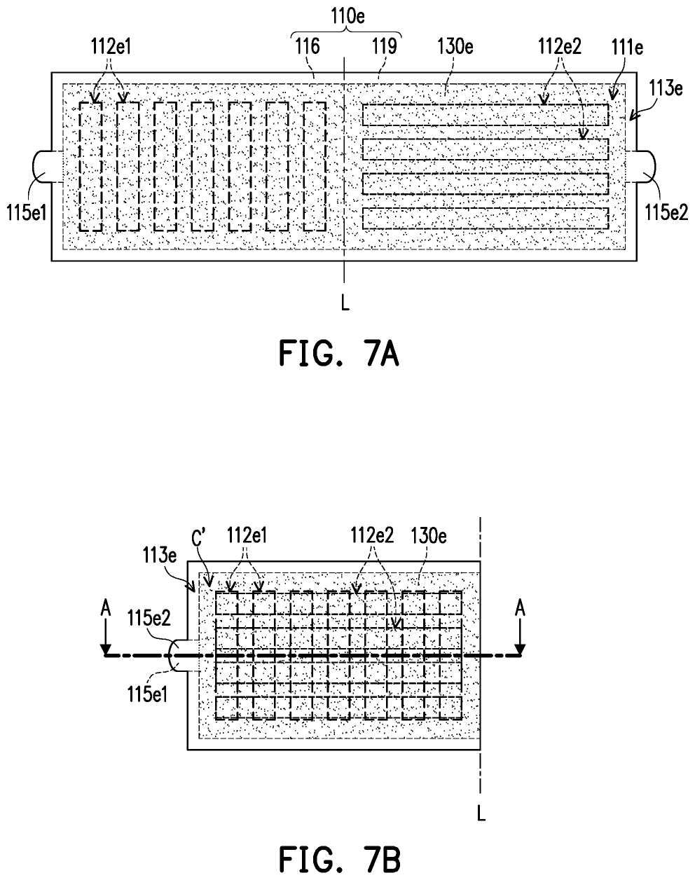

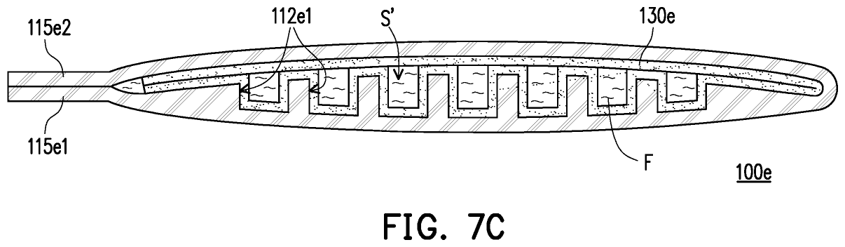

FIGS. 7A to 7C are schematic views of some steps of a manufacturing method of a vapor chamber structure according to another embodiment of the disclosure. To clearly illustrate the embodiment, FIG. 7C is a schematic cross-sectional view taken along a line A-A of FIG. 7B. The manufacturing method of a vapor chamber structure 100e (referring to FIG. 7C) of this embodiment is similar to the manufacturing method of the vapor chamber structure 100a (referring to FIG. 1D). The difference between the manufacturing method of the vapor chamber structure 100e and the manufacturing method of the vapor chamber structure 100a is: referring to FIG. 7A, a thermally conductive plate 110e is provided. The thermally conductive plate 110e has a configuration area 111e and a peripheral area 113e surrounding the configuration area 111e. Specifically, the thermally conductive plate 110e of this embodiment further has a first flap 115e1 and a second flap 115e2 opposite to each other, and the configuration area 111e connects the first flap 115e1 and the second flap 115e2. Here, a material of the thermally conductive plate 110e includes, for example, ceramics or a stacked material of a metal and an alloy. In the case where the material of the first thermally conductive plate 110e includes a stacked material of a metal and an alloy, the metal and the alloy are, for example, pure copper and a copper/nickel/silicon alloy, respectively, in which the thickness of the copper/nickel/silicon alloy is greater than the thickness of pure copper, and the overall structural strength is increased.

Next, referring to FIG. 7A again, at least one cavity (multiple cavities 112e1 and 112e2 are schematically shown) is formed in the configuration area 111e of the thermally conductive plate 110e. Specifically, the thermally conductive plate 110e includes a first thermally conductive portion 116 and a second thermally conductive portion 119. The cavity 112e1 is formed in the first thermally conductive portion 116, and the cavity 112e2 is formed in the second thermally conductive portion 119. An extension direction of the cavity 112e1 is perpendicular to an extension direction of the cavity 112e2.

Next, referring to FIG. 7A again, a capillary structure layer 130e is formed in the configuration area 111e of the thermally conductive plate 110e. The capillary structure layer 130e covers the configuration area 111e of the thermally conductive plate 110e and inner walls of the cavities 112e1 and 112e2, and the thickness of the capillary structure layer 130e is less than or equal to half of the thickness of the thermally conductive plate 110e. Here, a method of forming the capillary structure layer 130e is, for example, performing an etching process or an electroplating process or a printing process or a laser process or a sintering process on the thermally conductive plate 110e, so as to form the capillary structure layer 130e on a surface of the thermally conductive plate 110e. In other embodiments, the capillary structure layer may also be made of a porous medium, and a pore size of the porous medium is between 5 μm and 50 μm, which are still within the scope of the disclosure.

Next, referring to FIGS. 7A and 7B together, the thermally conductive plate 110e is folded in half along a fold line L, so that the first thermally conductive portion 116 and the second thermally conductive portion 119 are completely aligned, and the first flap 115e1 completely overlaps the second flap 115e2. Then, the peripheral area 113e of the thermally conductive plate 110e is sealed to form at least one chamber C′. The capillary structure layer 130e is located in the chamber C′, and only an overlapping area between the first flap 115e1 and the second flap 115e2 and the configuration area 111e are not sealed. Here, sealing the peripheral area 113e of the thermally conductive plate 110e may include a mechanical clamping process or a diffusion bonding process or a welding process or a soldering process or an adhesion process.

Next, referring to FIGS. 7B and 7C together, a vacuuming process is performed on the chamber C′, and the working fluid F is provided into the chamber C′. Specifically, the vacuuming process is performed on the chamber C′ between the first flap 115e1 and the second flap 115e2, and the working fluid F is provided into the chamber C′ between the first flap 115e1 and the second flap 115e2. Finally, the chamber C′ is completely sealed so as to form a sealed chamber S′, and the working fluid F is filled in the sealed chamber S′. It is to be noted that the sealed chamber S′ should not be fully filled with the working fluid F, because vapor generated by evaporation of the working fluid F requires space for movement. When the vapor chamber structure 100e is not heated, the working fluid F exists in the capillary structure layer 130e. After the vapor chamber structure 100e is heated, the working fluid F becomes vapor and enters the sealed chamber S′. When the vapor is condensed, the working fluid F returns into the capillary structure layer 130e. Here, a space between the first flap 115e1 and the second flap 115e2 is sealed to completely seal the chamber C′ to form the sealed chamber S′. Here, a method of completely sealing the chamber C′ is, for example, a mechanical clamping process or a diffusion bonding process or a welding process or a soldering process or an adhesion process, and the working fluid F is, for example, water. Up to this point, the manufacture of the vapor chamber structure 100e is completed.

In the manufacturing method of the vapor chamber structure 100e of this embodiment, the thermally conductive plate 110e is folded in half so that the capillary structure layer 130e is sandwiched between the first thermally conductive portion 116 and the second thermally conductive portion 119 of the thermally conductive plate 110e. Then, the peripheral area 113e of the thermally conductive plate 110e is sealed to form the chamber C′, the vacuuming process is performed on the chamber C′, and the working fluid F is provided into the chamber C′. Next, the chamber C′ is completely sealed, and the working fluid F is filled in the sealed chamber S′. Therefore, by manufacturing the thermally conductive shell of the vapor chamber structure 100e of this embodiment using the thermally conductive plate 110e, the vapor chamber structure 100e of this embodiment has a small thickness. In addition, the manufacture of the vapor chamber structure 100e of this embodiment is simple and low in cost.

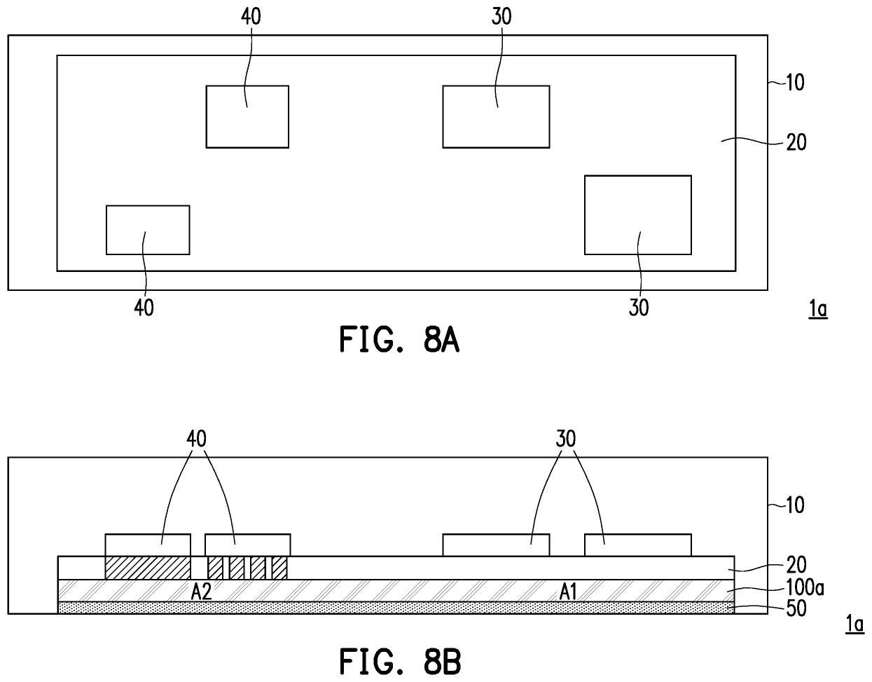

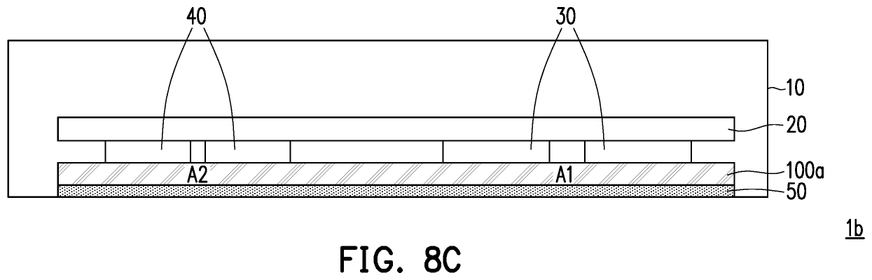

FIGS. 8A and 8B are respectively a schematic top view and a schematic cross-sectional view of an electronic device which adopts the vapor chamber structure of the disclosure. FIG. 8C is a schematic cross-sectional view of another electronic device which adopts the vapor chamber structure of the disclosure. To clearly illustrate the embodiment, FIG. 8A omits some members and is a perspective view.

In terms of application, referring to FIGS. 8A and 8B together, in this embodiment, an electronic product 1a is, for example, a mobile phone, which includes the vapor chamber structure 100a as shown in FIG. 1D, a shell 10, a circuit board 20, multiple non-heating devices (such as passive components) 30, multiple heating devices 40, and an adhering layer 50. The vapor chamber structure 100a is fixed on the shell 10 through the adhering layer 50 and is located between the circuit board 20 and the adhering layer 50. The non-heating devices 30 and the heating devices 40 are respectively configured on the circuit board 20, and the heating devices 40 are electrically connected to the circuit board 20. The non-heating devices 30 correspond to a condensation zone A1 of the vapor chamber structure 100a, and the heating devices 40 correspond to an evaporation zone A2 of the vapor chamber structure 100a. FIG. 8B is an example of a circuit board provided with a metal block or a metal-filled via hole therein to connect a heating device with an evaporation zone of a vapor chamber so as to transfer waste heat to a condensation zone. In another embodiment, referring to FIG. 8C, the non-heating device 30 and the heating device 40 of an electronic product 1b are located between the circuit board 20 and the vapor chamber structure 100a, which is still within the scope of the disclosure.

Since the vapor chamber structure 100a of this embodiment has a small thickness, it is adapted for being placed in the electronic product 1a and the electronic product 1b to facilitate heat dissipation for the electronic product 1a and the electronic product 1b.

In summary, in the manufacturing method of the vapor chamber structure of the disclosure, the capillary structure layer covers the thermally conductive plate and the inner wall of the cavity, and the chamber is formed by folding the thermally conductive plate in half and sealing the peripheral area of the thermally conductive plate. Next, the vacuuming process is performed on the chamber and the working fluid is provided into the chamber. Next, the chamber is completely sealed, and the working fluid is filled in the sealed chamber. Therefore, by manufacturing the thermally conductive shell of the vapor chamber structure of the disclosure using the thermally conductive plate, the vapor chamber structure of the disclosure has a small thickness. In addition, the manufacture of the vapor chamber structure of the disclosure is simple and low in cost.

Although the disclosure has been disclosed through the above embodiments, the embodiments are not intended to limit the disclosure. Those skilled in the art may make some changes and modifications without departing from the spirit and scope of the disclosure. Therefore, the scope of the disclosure shall be defined by the attached claims.

What is claimed is:

1. A vapor chamber structure, comprising:
a thermally conductive shell comprising a first thermally conductive portion and a second thermally conductive portion, wherein the first thermally conductive portion has at least one first cavity, and the second thermally conductive portion and the at least one first cavity define at least one sealed chamber, wherein a pressure in the at least one sealed chamber is lower than a standard atmospheric pressure;
a capillary structure layer covering an inner wall of the at least one sealed chamber; and
a working fluid filled in the at least one sealed chamber.

2. The vapor chamber structure according to claim 1, wherein the capillary structure layer comprises a first capillary structure portion and a second capillary structure portion, wherein the first capillary structure portion at least covers an inner wall of the at least one first cavity, and the second capillary structure portion is configured on the second thermally conductive portion.

3. The vapor chamber structure according to claim 2, wherein the first thermally conductive portion and the second thermally conductive portion are a thermally conductive plate that is integrally formed, and the thermally conductive shell is formed by folding the thermally conductive plate in half and then sealing the thermally conductive plate.

4. The vapor chamber structure according to claim 3, wherein the second thermally conductive portion has at least one second cavity, the second capillary structure portion at least covers an inner wall of the at least one second cavity, the at least one sealed chamber is defined between the thermally conductive plate, the at least one first cavity, and the at least one second cavity, and an extension direction of the at least one first cavity is different from an extension direction of the at least one second cavity.

5. The vapor chamber structure according to claim 2, wherein the thermally conductive shell is formed by overlapping the first thermally conductive portion and the second thermally conductive portion and then sealing the first thermally conductive portion and the second thermally conductive portion, and the first thermally conductive portion and the second thermally conductive portion are a first thermally conductive plate and a second thermally conductive plate, respectively.

6. The vapor chamber structure according to claim 5, wherein the second thermally conductive plate has at least one second cavity, the second capillary structure portion at least covers an inner wall of the at least one second cavity, and the at least one sealed chamber is defined between the first thermally conductive plate, the second thermally conductive plate, the at least one first cavity and the at least one second cavity.

7. The vapor chamber structure according to claim 1, wherein the capillary structure layer is a porous structure layer or a surface microstructure layer of the thermally conductive shell.

8. The vapor chamber structure according to claim 1, wherein a material of the thermally conductive shell comprises ceramics or a stacked material of a metal and an alloy.

9. The vapor chamber structure according to claim 1, wherein the working fluid comprises water.

10. The vapor chamber structure according to claim 1, wherein a thickness of the capillary structure layer is less than or equal to half of a thickness of the thermally conductive shell.

11. A manufacturing method of a vapor chamber structure, comprising:
providing a thermally conductive plate, wherein the thermally conductive plate has a configuration area and a peripheral area surrounding the configuration area;
forming at least one cavity in the configuration area of the thermally conductive plate;
forming a capillary structure layer in the configuration area of the thermally conductive plate, wherein the capillary structure layer covers the thermally conductive plate and an inner wall of the at least one cavity;
folding the thermally conductive plate in half and sealing the peripheral area of the thermally conductive plate to form at least one chamber, wherein the capillary structure layer is located in the at least one chamber;
performing a vacuuming process on the at least one chamber and providing a working fluid into the at least one chamber; and
completely sealing the at least one chamber to form at least one sealed chamber.

12. The manufacturing method of a vapor chamber structure according to claim 11, wherein the thermally conductive plate has a first flap and a second flap opposite to each other, and the configuration area connects the first flap and the second flap, and the manufacturing method of a vapor chamber structure further comprises:
performing the vacuuming process on the at least one chamber between the first flap and the second flap, and providing the working fluid into the at least one chamber between the first flap and the second flap; and
sealing a space between the first flap and the second flap so as to completely seal the at least one chamber.

13. The manufacturing method of a vapor chamber structure according to claim 11, wherein a method of forming the capillary structure layer comprises performing an etching process or an electroplating process or a printing process or a laser process or a sintering process on the thermally conductive plate, and forming the capillary structure layer on a surface of the thermally conductive plate.

14. The manufacturing method of a vapor chamber structure according to claim 11, wherein the capillary structure layer is made of a porous medium, and a pore size of the porous medium is between 5 μm and 50 μm.

15. The manufacturing method of a vapor chamber structure according to claim 11, wherein a method of completely sealing the at least one chamber comprises a mechanical clamping process or a diffusion bonding process or a welding process or a soldering process or an adhesion process.

16. A manufacturing method of a vapor chamber structure, comprising:
providing a first thermally conductive plate and a second thermally conductive plate, wherein the first thermally conductive plate has a first configuration area and a first peripheral area surrounding the first configuration area, and the second thermally conductive plate has a second configuration area and a second peripheral area surrounding the second configuration area;
forming at least one first cavity in the first configuration area of the first thermally conductive plate;
forming a first capillary structure portion on an inner wall of the at least one first cavity;
forming a second capillary structure portion in the second configuration area of the second thermally conductive plate;
superimposing the second thermally conductive plate on the first thermally conductive plate and sealing the first peripheral area of the first thermally conductive plate and the second peripheral area of the second thermally conductive plate to form at least one chamber, wherein the first capillary structure portion and the second capillary structure portion define a capillary structure layer, and the capillary structure layer is located in the at least one chamber;
performing a vacuuming process on the at least one chamber and providing a working fluid into the at least one chamber; and
completely sealing the at least one chamber so as to form at least one sealed chamber.

17. The manufacturing method of a vapor chamber structure according to claim 16, wherein the first thermally conductive plate has a first flap, and the second thermally conductive plate has a second flap, and the manufacturing method of a vapor chamber structure further comprises:
having the second flap overlap the first flap when superimposing the second thermally conductive plate on the first thermally conductive plate,
performing the vacuuming process on the at least one chamber between the first flap and the second flap, and providing the working fluid into the at least one chamber between the first flap and the second flap; and
sealing a space between the first flap and the second flap so as to completely seal the at least one chamber.

18. The manufacturing method of a vapor chamber structure according to claim 16, wherein a method of forming the first capillary structure portion and the second capillary structure portion comprises performing an etching process or an electroplating process or a printing process or a laser process or a sintering process on the first thermally conductive plate and the second thermally conductive plate respectively and forming the first capillary structure portion on a first surface of the first thermally conductive plate and forming the second capillary structure portion on a second surface of the second thermally conductive plate.

19. The manufacturing method of a vapor chamber structure according to claim 16, wherein a method of completely sealing the at least one chamber comprises a mechanical clamping process or a diffusion bonding process or a welding process or a soldering process or an adhesion process.

20. The manufacturing method of a vapor chamber structure according to claim 16, comprising: before forming the second capillary structure portion in the second configuration area of the second thermally conductive plate, forming at least one second cavity in the second configuration area of the second thermally conductive plate.
